(19) United States
(12) Patent Application Publication
(10) Pub. No.: US 2014/0284783 A1
(43) Pub. Date: Sep. 25, 2014

(54) SEMICONDUCTOR DEVICE

(71) Applicant: Kabushiki Kaisha Toshiba, Minato-ku (JP)

(72) Inventor: Satoshi SAYAMA, Kanagawa-ken (JP)

(73) Assignee: Kabushiki Kaisha Toshiba, Minato-ku (JP)

(21) Appl. No.: 14/026,195

(22) Filed: Sep. 13, 2013

(30) Foreign Application Priority Data
Mar. 22, 2013 (JP) 2013-061149

(51) Int. Cl. H01L 23/34

(52) U.S. Cl. CPC H01L 23/34
USPC 257/690; 257/712

(57) ABSTRACT

According to one embodiment, a semiconductor device includes: a heat sink; a semiconductor element provided on a mounting surface of the heat sink; and a sealing body wrapping the heat sink and the semiconductor element, a thickness of a portion of the sealing body on a side of a surface on an opposite side to the mounting surface of the heat sink being smaller than a thickness of a portion of the sealing body on the mounting surface side of the heat sink. A first concave-convex is provided on the surface on an opposite side to the mounting surface of the heat sink. A second concave-convex larger than the first concave-convex is provided on a surface crossing the surface on an opposite side to the mounting surface of the heat sink.

### CROSS-REFERENCE TO RELATED APPLICATIONS

This application is based upon and claims the benefit of priority from Japanese Patent Application No. 2013-061149, filed on Mar. 22, 2013; the entire contents of which are incorporated herein by reference.

### FIELD

Embodiments described herein relate generally to a semiconductor device.

### BACKGROUND

Heat dissipation properties and insulating properties are often required for a semiconductor device in which a semiconductor element is sealed with a resin or the like. For example, high heat dissipation properties and electrical insulating properties are required for a semiconductor device using a semiconductor element such as a switching element such as a MOSFET (metal-oxide-semiconductor field effect transistor), a HEMT (high electron mobility transistor), and an IGBT (insulated gate bipolar transistor) and a diode used for power control etc.

### BRIEF DESCRIPTION OF THE DRAWINGS

FIG. 1 is a schematic cross-sectional view illustrating a semiconductor device according to a first embodiment;

FIG. 2 is a schematic plan view showing the internal structure thereof;

FIG. 3 is a schematic cross-sectional view illustrating a use manner of the semiconductor device of the embodiment;

FIGS. 4A and 4B are schematic views showing a method for manufacturing the semiconductor device;

FIG. 5 is a schematic view showing a method for manufacturing the semiconductor device;

FIGS. 6A and 6B are schematic views showing another method for manufacturing the semiconductor device of the embodiment;

FIG. 7 is a conceptual view showing a distribution of stress resulting from the thermal contraction of the sealing body;

FIGS. 8A to 8C are schematic partial cross-sectional views illustrating configurations of the concave-convex;

FIG. 9 is a schematic cross-sectional view illustrating a semiconductor device according to the second embodiment;

FIG. 10 is a schematic view illustrating a method for manufacturing the semiconductor device of the embodiment;

FIGS. 11A and 11B are schematic views illustrating another method for manufacturing the semiconductor device of the embodiment; and

FIG. 12 is a schematic cross-sectional view illustrating a semiconductor device according to the third embodiment.

### DETAILED DESCRIPTION

In general, according to one embodiment, a semiconductor device includes: a heat sink; a semiconductor element provided on a mounting surface of the heat sink; and

a sealing body wrapping the heat sink and the semiconductor element, a thickness of a portion of the sealing body on a side of a surface on an opposite side to the mounting surface of the heat sink being smaller than a thickness of a portion of the sealing body on the mounting surface side of the heat sink. A first concave-convex is provided on the surface on an opposite side to the mounting surface of the heat sink. A second concave-convex larger than the first concave-convex is provided on a surface crossing the surface on an opposite side to the mounting surface of the heat sink.

In general, according to another embodiment, a semiconductor device includes: a heat sink; a semiconductor element provided on a mounting surface of the heat sink; and a sealing body wrapping the heat sink and the semiconductor element, a thickness of a portion of the sealing body on a side of a surface on an opposite side to the mounting surface of the heat sink being smaller than a thickness of a portion of the sealing body on the mounting surface side of the heat sink. The sealing body has a first portion on a side of a surface on an opposite side to the mounting surface of the heat sink and a second portion including at least part of a portion on the mounting surface side of the heat sink. A material of the second portion is different from a material of the first portion. A thermal conductivity of the first portion is higher than a thermal conductivity of the second portion.

Various embodiments will be described hereinafter with reference to the accompanying drawings.

The drawings are schematic or conceptual; and the relationships between the thickness and width of portions, the proportions of sizes among portions, etc. are not necessarily the same as the actual values thereof. Further, the dimensions and proportions may be illustrated differently among drawings, even for identical portions.

In the specification of this application and the drawings, components similar to those described in regard to a drawing thereinabove are marked with the same reference numerals, and a detailed description is omitted as appropriate.

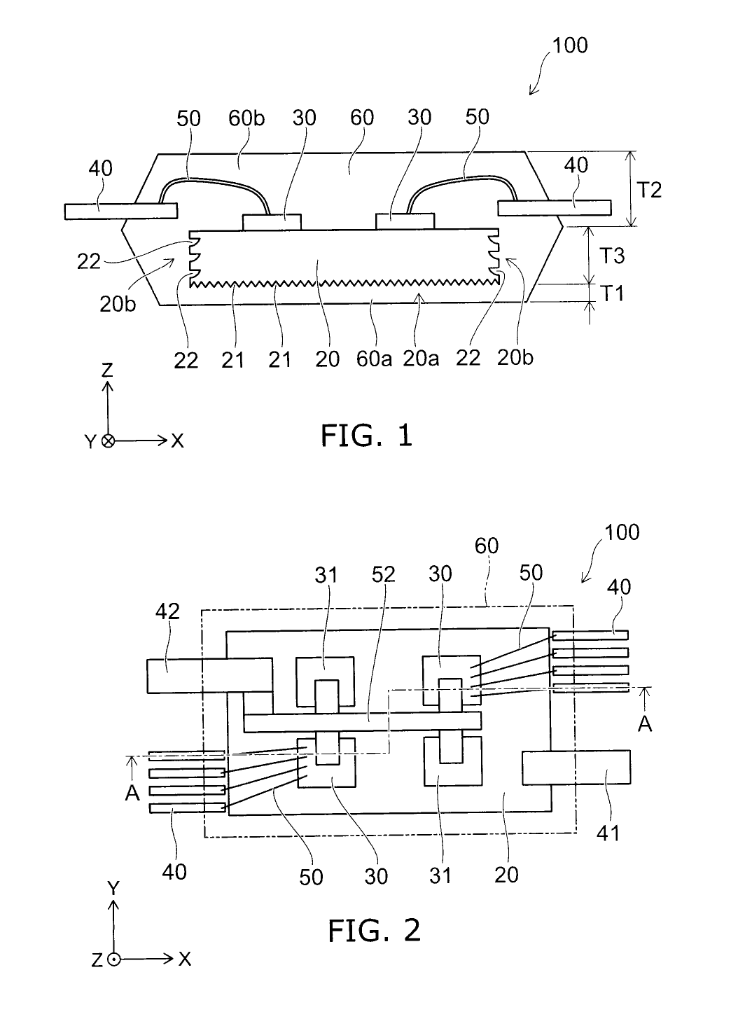

FIG. 1 is a schematic cross-sectional view illustrating a semiconductor device according to a first embodiment.

FIG. 2 is a schematic plan view showing the internal structure thereof. FIG. 1 shows an end surface of a cross section taken along line A-A in FIG. 2.

A semiconductor device 100 of the embodiment includes a die pad (heat sink) 20, semiconductor elements 30 and 31 mounted on the mounting surface of the die pad 20, leads 40, 41, and 42, a wire 50 electrically connecting the semiconductor element 30 and the lead 40, and a sealing body 60 exposing end portions of the leads 40, 41, and 42 and sealing the other portions. In FIG. 2, the outer edge of the sealing body 60 is shown by an alternate long and two short dashes line.

The die pad 20 serves to support the semiconductor elements 30 and 31, and is made of a conductive material. When a metal is used as the material of the die pad 20, the dissipation of the heat released from the semiconductor elements 30 and 31 to the outside can be promoted. As such a metal, for example, copper (Cu) or an alloy thereof and iron (Fe) or an alloy thereof may be given.

The semiconductor elements 30 and 31 are a switching element, a diode, or the like, for example. In the case of the specific example shown in FIG. 2, the semiconductor element 30 is an IGBT, and the semiconductor element 31 is a diode. However, the invention is not limited to this specific example, and various semiconductor elements can be similarly used. The semiconductor elements 30 and 31 are bonded to the die pad 20 by solder, for example. Alternatively, in a broader sense, a metal material may be used as the bonding medium to bond the semiconductor elements 30 and 31 to the die pad 20.

The lead 40 (a first lead) is connected to the semiconductor element 30 by the wire 50. The lead 41 (a second lead) is connected to the die pad 20. The lead 42 is connected to the semiconductor elements 30 and 31 via a connection bar 52. The lead 40 is used as a control electrode, and the leads 41 and 42 are used as main electrodes, as an example.

The leads 40, 41, and 42 contain a conductive material. A metal may be given as such a material, for example. The lead 40 may contain the same kind of material as the die pad 20.

Also the wire 50 contains a conductive material. A metal may be given as such a material, for example. When gold (Au), aluminum (Al), copper (Cu), or the like is used for the wire 50, a large current can be easily passed through the wire 50. The leads 40, 41, and 42 and the wire 50 are not essential in the embodiment.

The sealing body 60 seals the die pad 20, the semiconductor elements 30 and 31, the inside portions of the leads 40, 41, and 42, and the wire 50. That is, the sealing body 60 is provided so as to wrap these components. A resin may be used as the material of the sealing body 60, for example. Examples of the resin include an epoxy resin, polyphenylene sulfide (PPS), polystyrene, a liquid crystal polymer, and the like. Of these, an epoxy resin and polyphenylene sulfide are excellent particularly in thermal conductivity and electrical insulating properties.

The thermal conductivity can be improved by adding a filler to the sealing body 60. When ensuring also insulating properties is taken into consideration, the material of the filler is preferably an insulator, and specifically a ceramic is preferably used. As such a ceramic, for example, alumina, magnesia, silica (SiC), aluminum nitride, and the like may be given. Of these, when alumina or silica is added as the filler, the effect of improving the thermal conductivity and the effect of reducing the thermal stress of the resin are high.

In the semiconductor device 100 of the embodiment, the thickness T1 of a portion of the sealing body 60 below the die pad 20, that is, a portion 60a on the side of the surface on the opposite side to the mounting surface of the die pad 20 is smaller than the thickness T2 of a portion above the die pad 20, that is, a portion 60b on the mounting surface side of the die pad 20. By setting smaller the thickness T1 of the portion 60a on the lower side of the die pad 20, the heat released from the semiconductor elements 30 and 31 toward the die pad 20 can be dissipated downward with low thermal resistance. When an epoxy resin is used as the material of the sealing body 60 and alumina or the like is added as the filler, the thermal conductivity of the sealing body 60 can be increased to approximately 3 W/mK to 10 W/mK, for example. High heat dissipation performance can be ensured by thinning the thickness T1 to 1 millimeter or less, or further to approximately 500 micrometers.

The heat dissipation performance is improved as the thickness T1 of the sealing body 60 is made thinner. However, when the thickness T1 is thin, the electrical insulating properties and the dielectric breakdown voltage tend to decrease. From this point of view, when an epoxy resin is used as the material of the sealing body 60, the thickness T1 is preferably set within a range from 0.1 to 0.5 millimeters, for example.

On the other hand, the thickness T2 of the portion 60b of the sealing body 60 above the die pad 20 is set to a height necessary to seal the semiconductor elements 30 and 31 and the wire 50. The thickness T2 may be approximately 5 millimeters, as an example.

In the embodiment, the lower surface 20a of the die pad 20 is provided with a concave-convex (first concave-convex) 21, and also the side surface, that is, the surface 20b crossing the surface on the opposite side to the mounting surface of the die pad 20 is provided with a concave-convex (second concave-convex) 22. The concave-convex 22 is larger than the concave-convex 21. This is described in detail later.

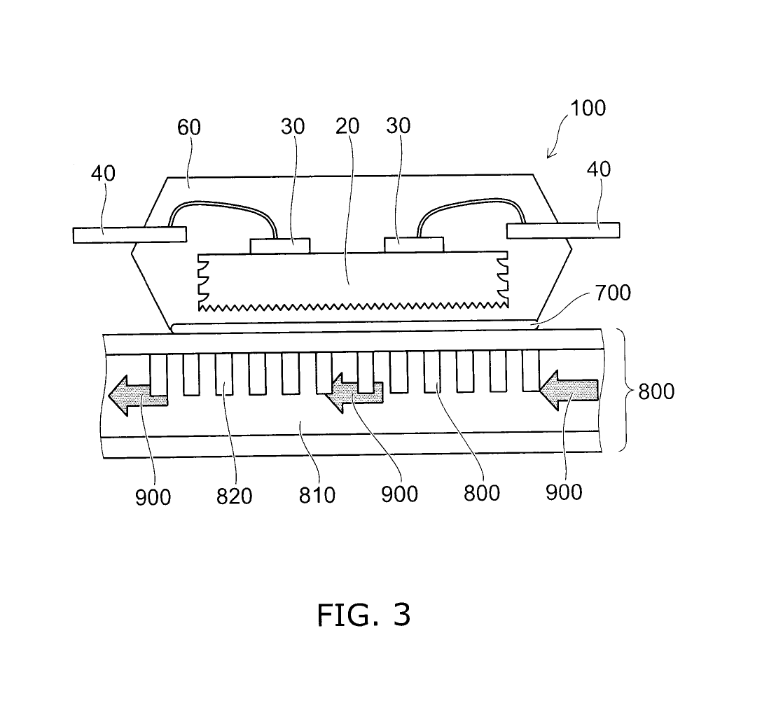

FIG. 3 is a schematic cross-sectional view illustrating a use manner of the semiconductor device 100 of the embodiment.

The semiconductor device 100 may be used to be bonded to a heat sink 800 by heat dissipation grease 700, for example. In the heat sink 800, a heat dissipation path 810 is provided, and heat dissipation fins 820 are provided as appropriate. A refrigerant 900 such as liquid and gas is allowed to flow through the heat dissipation path 810 as appropriate.

The heat generated in the semiconductor elements 30 and 31 is released from the lower surface 20a of the die pad 20 via the sealing body 60. The released heat is dissipated to the heat sink 800 via the heat dissipation grease 700.

By the embodiment, the heat dissipation efficiency can be improved by thinning the thickness T1 of the portion 60a of the sealing body 60 below the die pad.

Next, a method for manufacturing the semiconductor device 100 of the embodiment is described.

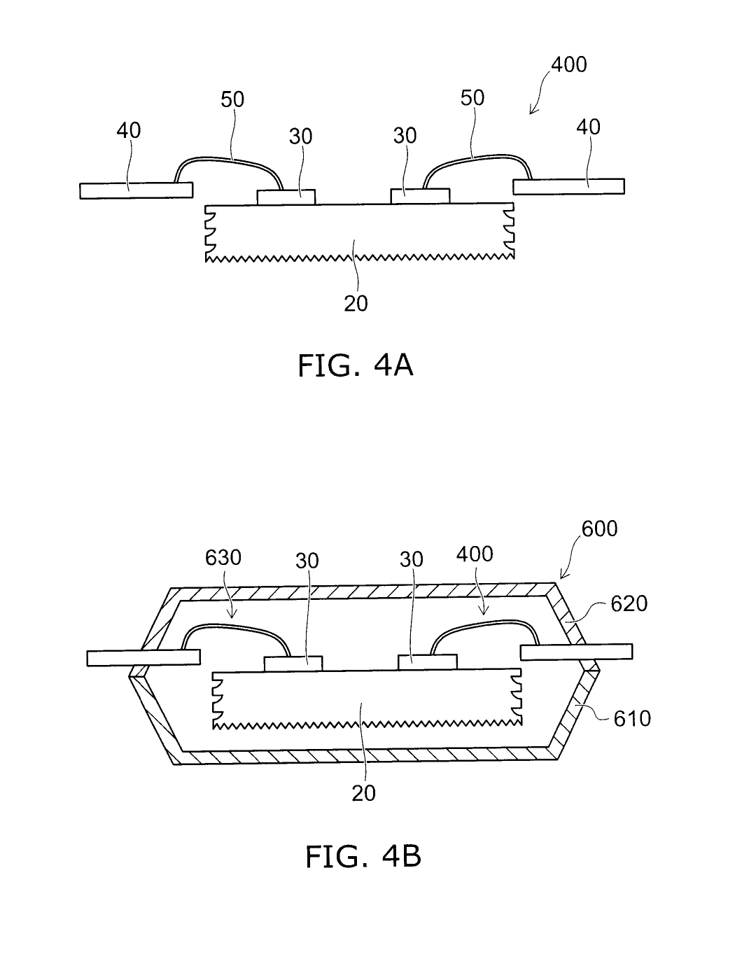

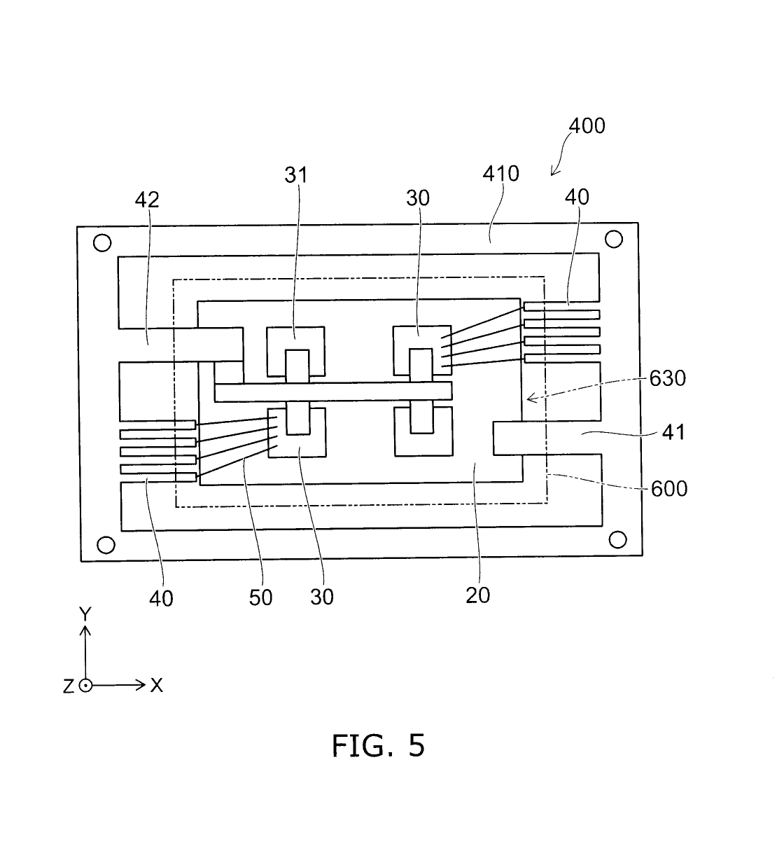

FIGS. 4A and 4B and FIG. 5 are schematic views showing a method for manufacturing the semiconductor device 100.

First, as shown in FIG. 4A, the semiconductor element 30 (31) is mounted on the mounting surface of the die pad 20 of a lead frame 400. Then, the semiconductor element 30 and the lead 40 are connected together by the wire 50. Also the joining of the connection bar 52 described above in regard to FIG. 2 etc. are performed as appropriate.

After that, as shown in FIG. 4B, the lead frame 400 is placed in the cavity of a mold 600. The mold 600 is divided into a lower mold 610 and an upper mold 620, for example, and can fix the lead frame 400 between these molds.

FIG. 5 is a schematic view illustrating the relationship between the lead frame 400 and the cavity of the mold 600. In FIG. 5, the outer edge of the cavity 630 of the mold 600 is shown by an alternate long and two short dashes line.

The lead frame 400 includes a frame 410. The leads 40, 41, and 42 are supported by the frame 410.

In a state where the lead frame 400 is placed in the cavity 630 of the mold 600 in this way, the mold 600 is heated to approximately 180° C., for example, and a resin is put into the cavity 630 from a not-shown injection port (gate). The resin is put into the cavity 630 by a method called transfer molding, injection molding, or the like and is cured, for example; thus, the sealing body 60 can be formed.

Usually a thermosetting resin is used as the resin to be put in. Thus, a molten resin is put in and then cured to form the sealing body 60. After that, cooling is performed, and the workpiece is taken out of the mold 600.

After that, the frame 410 of the lead frame 400 and the leads 40, 41, and 42 are separated, and the semiconductor device 100 is completed.

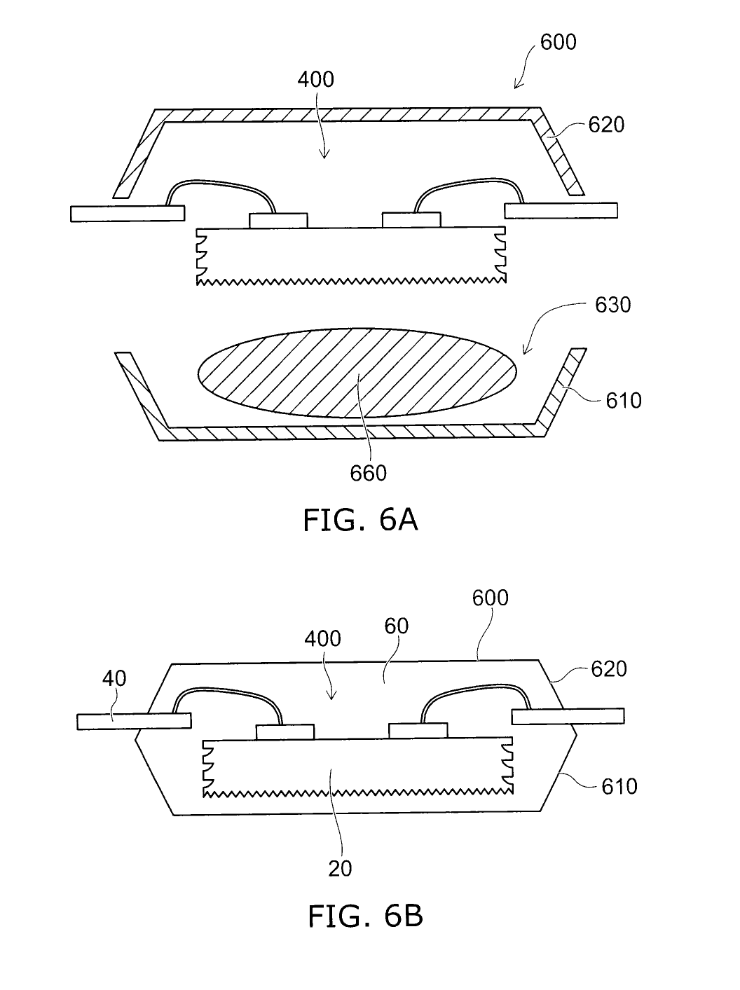

FIGS. 6A and 6B are schematic views showing another method for manufacturing the semiconductor device 100 of the embodiment.

That is, FIGS. 6A and 6B show a manufacturing method using the compression molding method.

In the case of using the compression molding method, a resin 660 in a granular or powder form is put into the cavity 630 of the mold 600 beforehand. Also in the compression molding method, usually a thermosetting resin is used.

Then, the lead frame 400 is placed in the cavity 630, and heating is performed to approximately 180° C., for example. The resin 660 is softened and melted to be spread in the cavity 630, and is then cured to form the sealing body 60. After that, cooling is performed, the workpiece is taken out of the mold 600, and the frame 410 of the lead frame 400 is separated; thus, the semiconductor device 100 is completed.

Hereinabove, methods for manufacturing the semiconductor device 100 are described with reference to FIG. 4A to FIG. 6B.

Both methods need, when forming the sealing body 60, processes of performing heating to approximately 180° C. to cure the resin and then performing cooling, for example.

Here, a problem is the thermal contraction of the sealing body 60 in the cooling process.

Returning to FIG. 1, a description is further given. As described above, the semiconductor device 100 has a structure in which the die pad 20 is sealed with the sealing body 60. The thickness T2 of the sealing body 60 above the die pad 20 (the portion on the mounting surface side of the die pad 20) is larger than the thickness T1 of the sealing body 60 below the die pad 20 (the portion on the side of the surface on the opposite side to the mounting surface of the die pad 20). For example, the thickness T1 is approximately 0.1 to 0.5 millimeters, whereas the thickness T2 is approximately 5 millimeters; T2 may be ten times or more of T1.

On the other hand, the thermal expansion coefficient of the die pad 20 is smaller than the thermal expansion coefficient of the sealing body 60. When an epoxy resin is used for the sealing body 60, the linear expansion coefficient thereof is approximately 40 to 80×10⁻⁶/° C., for example. In contrast, when copper (Cu) is used for the die pad 20, the linear expansion coefficient thereof is as small as approximately 16.8×10⁻⁶/° C.

If the expansion coefficients of the sealing body 60 and the die pad 20 are approximately the same, the whole of them can thermally expand or thermally contract almost uniformly. However, when the die pad 20 has a smaller expansion coefficient than the sealing body 60, an imbalance occurs in the thermal contraction of the sealing body 60. In other words, the behavior of the thermal contraction of the sealing body 60 is divided between the portion 60b on the upper side of the die pad 20 and the portion 60a on the lower side.

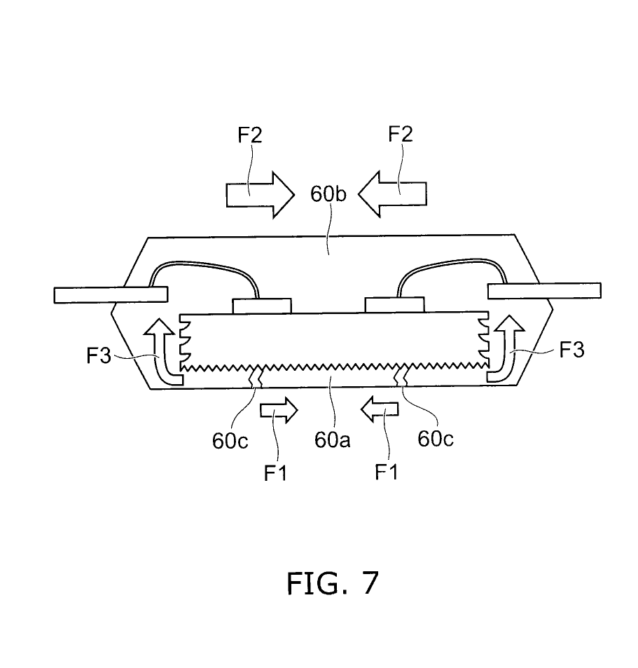

FIG. 7 is a conceptual view showing a distribution of stress resulting from the thermal contraction of the sealing body 60.

As described above, the thickness T2 of the portion 60b above the die pad 20 of the sealing body 60 is much larger than the thickness T1 of the portion 60a below the die pad 20. In other words, the capacity (volume) of the portion 60b above the die pad 20 of the sealing body 60 is larger than the capacity (volume) of the portion 60a below the die pad 20. As a result, in regard to the stress resulting from the thermal contraction of the sealing body 60, the stress F2 in the portion 60b above the die pad 20 is larger than the stress F1 in the portion 60a below the die pad 20.

Since the thermal contraction of the die pad 20 is smaller than that of the sealing body 60, the portion 60b above the die pad 20 cannot contract together with the die bad 20. As a result, tensile stress F3 is applied to the portion 60a below the die pad 20.

Since the thickness T1 of the portion 60a below the die pad 20 is small, when such tensile stress F3 is further applied in addition to the compressing stress F2 that has already been produced due to the cooling, a defect 60c such as a fracture, a crack, and peeling may occur in the thin portion 60a.

The problem of thermal contraction described above may similarly occur not only in the manufacturing of the semiconductor device 100 but also in cooling following an increase in the temperature of the semiconductor device 100 used for power control etc.

In contrast, in the embodiment, the concave-convex 22 is provided on the side surface of the die pad 20, that is, the surface 20b crossing the surface on the opposite side to the mounting surface of the die pad 20. The concave-convex 22 is larger than the concave-convex 21 of the lower surface 20a of the die pad 20. By providing the concave-convex 22 like this, the resin of the sealing body 60 can be fixed at this portion and the tensile stress F3 can be suppressed. In other words, by providing the concave-convex 22, the shift or movement of the resin of the sealing body 60 can be suppressed at the side surface 20b of the die pad 20. Consequently, the application of the tensile stress F3 to the portion 60a on the lower side of the die pad 20 of the sealing body 60 can be suppressed, and the occurrence of the defect 60c in the thin portion 60a can be prevented.

The concave-convex 22 provided on the side surface 20b of the die pad 20 is preferably made large to some extent because the effect of fixing the resin of the sealing body 60 is increased. For the size of the concave-convex 22, the surface roughness Ra of the concave-convex 22 is preferably ten times or more of the Ra of the concave-convex 21 of the lower surface 20a, for example. The depth of the concave-convex 22 may be approximately 1 millimeter, for example.

The configuration of the concave-convex 22 needs to suppress the stress F3 applied upward at the side surface 20b. Thus, it is preferable to appropriately design also the configuration of the concave-convex 22.

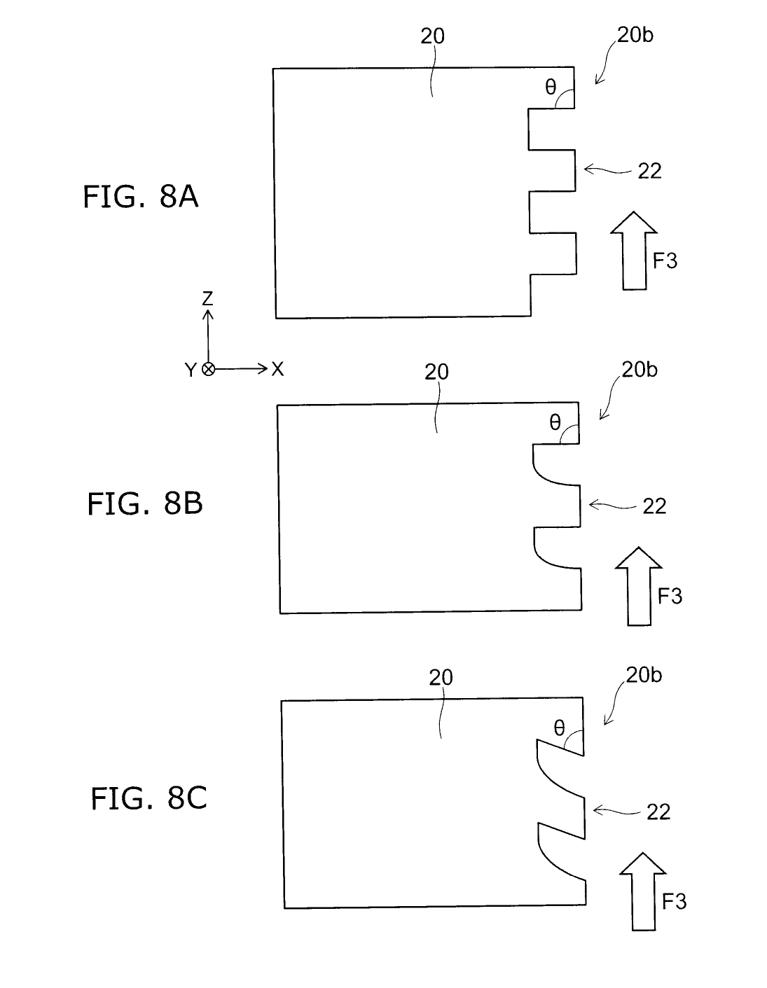

FIGS. 8A to 8C are schematic partial cross-sectional views illustrating configurations of the concave-convex 22.

The concave-convex 22 may have a substantially perpendicular trench configuration on the side surface 20b of the die pad 20 as shown in FIG. 8A, for example. Here, the angle θ between the upper wall surface of the concave and the side surface 20b is 90 degrees, for example.

In the embodiment, it is necessary to suppress the stress F3 applied upward along the side surface 20b of the die pad 20. Hence, when the angle between the upper side surface of the concave and the side surface 20b is made small, the resin can be caught and fixed, and the movement in the direction of the stress F3 can be suppressed.

As shown in FIG. 8B, the angle θ between the upper wall surface of the concave and the side surface 20b is approximately 90 degrees, and the upper wall surface of the concave may be a gently inclined surface.

As shown in FIG. 8C, when the angle θ between the upper wall surface of the concave and the side surface 20b is set to an acute angle smaller than 90 degrees, the effect of preventing the movement and shift of the resin in the direction of the stress F3 is further increased.

The configuration of the concave-convex 22 preferably has a portion extending in a direction parallel to the lower surface 20a of the die pad 20. As an example of the configuration of the concave-convex 22, a trench extending in the horizontal direction (the Y direction of FIG. 1 and FIGS. 8A to 8C) may be given. The concave-convex 22 is in a trench configuration extending in a direction parallel to the die pad 20, for example. Such a trench may be discontinuous in the Y direction. Alternatively, the configuration of the concave-convex 22 may be a spot configuration or a dot configuration.

As describe above, by the embodiment, the heat dissipation performance can be improved by setting the thickness of the portion 60a on the lower side of the die pad 20 of the sealing body 60 thinner than the thickness of the portion 60b on the upper side. Furthermore, the defect 60c of the sealing body 60 resulting from thermal contraction can be suppressed by making the concave-convex 22 provided on the side surface 20b of the die pad 20 larger than the concave-convex 21 provided on the lower surface 20a.

Consequently, a semiconductor device 100 can be provided that can be stably manufactured with high yield and can stably operate with high reliability even when it is used while heating and cooling are repeated.

Next, a second embodiment of the invention is described.

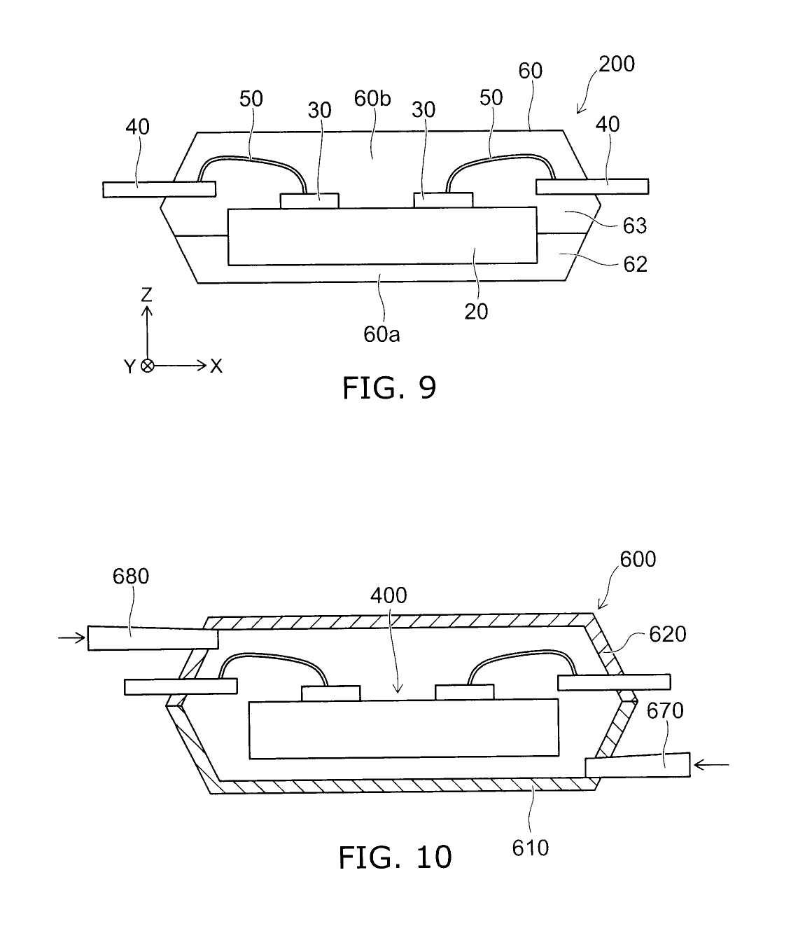

FIG. 9 is a schematic cross-sectional view illustrating a semiconductor device according to the second embodiment.

In a semiconductor device 200, the sealing body 60 has a first portion 62 and a second portion 63. The first portion 62 includes a portion on the lower side of the die pad 20, that is, the portion 60a on the side of the surface on the opposite side to the mounting surface of the die pad 20. The second portion 63 includes a portion on the upper side of the die pad 20, that is, at least part of the portion 60b on the mounting surface side of the die pad 20. The material of the first portion 62 and the material of the second portion 63 are different. In the specification of this application, “different material” includes the case where the composition or the amount of adhesive is different, for example. Thus, materials in which a filler is added to an epoxy resin at different concentrations fall under “different materials,” for example.

The heat dissipation effect can be enhanced by using a material with good thermal conductivity as the material of the first portion 62. In this case, when a less expensive material is used as the material of the second portion 63, a semiconductor device 200 with high heat dissipation effect is obtained while costs are reduced. As an example, a structure in which the percentage of contained fillers that increase the thermal conductivity of the resin is high in the first portion 62 and low in the second portion 63 may be used. Alternatively, a resin with a high thermal conductivity and high costs may be used for the first portion, and a resin with a low thermal conductivity and low costs may be used for the second portion.

On the other hand, in the embodiment, the linear expansion coefficients of the first portion 62 and the second portion 63 may be varied. That is, when a resin with a smaller linear expansion coefficient than the first portion 62 is used as the material of the second portion 63, the occurrence of the stress F3 described above in regard to FIG. 7 can be lessened. Consequently, the occurrence of the defect 60c in the portion 60a on the lower side of the die pad 20 can be suppressed. In this case, there is a case where it is not necessary to provide the concave-convexes 21 and 22 of the die pad 20 like those described above in regard to the first embodiment.

FIG. 10 is a schematic view illustrating a method for manufacturing the semiconductor device 200 of the embodiment.

The semiconductor device 200 of the embodiment can be manufactured by double molding.

Specifically, the lead frame 400 is placed in the mold 600, a resin 670 is injected from an injection port (gate) provided at the lower mold 610, and a resin 680 is injected from an injection port (gate) provided at the upper mold 620, for example. One of the resins 670 and 680 is injected and cured earlier, and the other resin is injected and cured later. The resin 670 forms the first portion 62 of the sealing body 60, and the resin 680 forms the second portion 63.

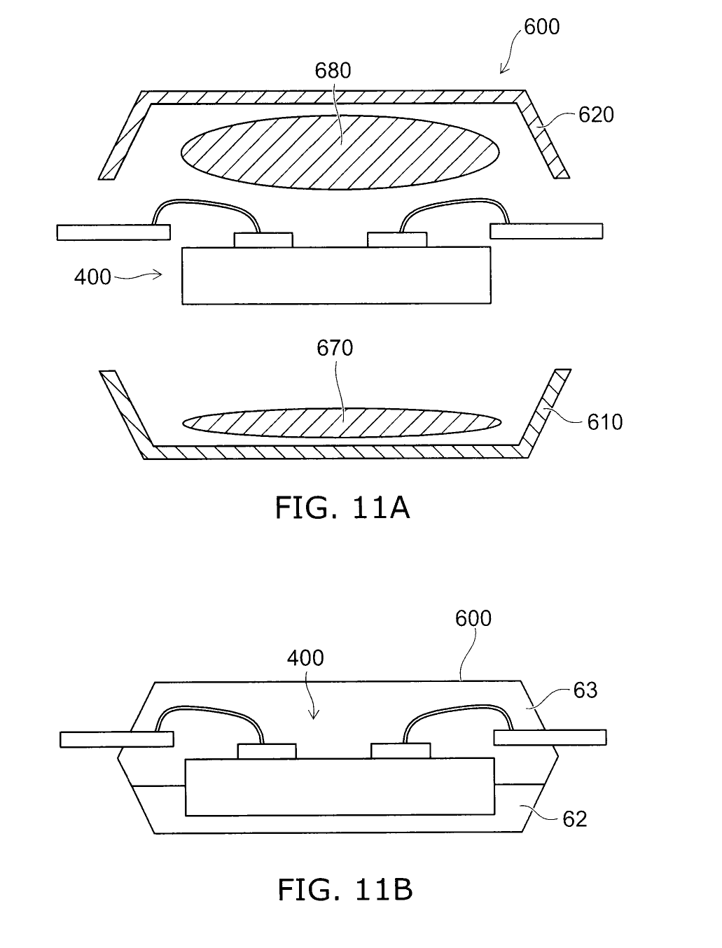

FIGS. 11A and 11B are schematic views illustrating another method for manufacturing the semiconductor device 200 of the embodiment.

That is, FIGS. 11A and 11B show a manufacturing method using the compression molding method.

In the case of using the compression molding method, the resin 670 and the resin 680 in a granular or powder form are put into the cavity 630 of the mold 600 beforehand. The resin 670 is put into the lower side of the lead frame 400, and the resin 680 is put into the upper side of the lead frame 400.

Then, heating is performed to approximately 180° C., for example, in a state where the lead frame 400 is placed in the cavity 630. The resin 670 and the resin 680 are softened and melted, and are then cured to form the sealing body 60. At this time, the resin 670 forms the first portion 62, and the resin 680 forms the second portion 63.

After that, cooling is performed, the workpiece is taken out of the mold 600, and the frame 410 of the lead frame 400 is separated; thus, the semiconductor device 100 is completed.

By methods like those described above, the semiconductor device 200 of the second embodiment can be manufactured.

Next, a third embodiment of the invention is described.

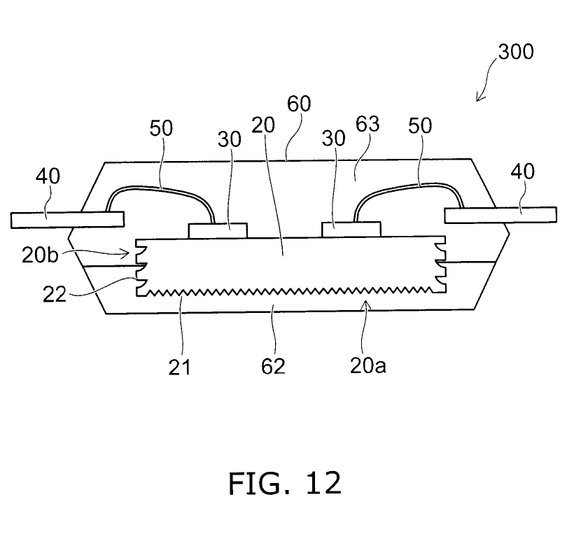

FIG. 12 is a schematic cross-sectional view illustrating a semiconductor device according to the third embodiment.

The embodiment is a combination of the first embodiment and the second embodiment. That is, a semiconductor device 300 has the concave-convexes 21 and 22 on the lower surface 20a and the side surface 20b, respectively, of the die pad 20. Similarly to the second embodiment, the sealing body 60 has the first portion 62 and the second portion 63. The first portion 62 includes the portion 60a on the lower side of the die pad 20. The second portion 63 includes at least part of the portion 60b on the upper side of the die pad 20.

By the embodiment, the heat dissipation performance can be improved by setting the thickness of the portion 60a on the lower side of the die pad 20 of the sealing body 60 thinner than the thickness of the portion 60b on the upper side. Furthermore, the defect 60c of the sealing body 60 resulting from thermal contraction can be suppressed by making the concave-convex 22 provided on the side surface 20b of the die pad 20 larger than the concave-convex 21 provided on the lower surface 20a.

Furthermore, the heat dissipation effect can be enhanced by using a material with good thermal conductivity as the material of the first portion 62. In this case, when a less expensive material is used as the material of the second portion 63, a semiconductor device 200 with high heat dissipation effect is obtained while costs are reduced.

On the other hand, when a resin with a smaller linear expansion coefficient than the first portion 62 is used as the material of the second portion 63, the occurrence of the tensile stress F3 (FIG. 7) applied in cooling can be lessened. Consequently, by combination with the effect of the concave-convex 22 of the side surface 20b of the die pad 20, the occurrence of the defect 60c in the portion 60a on the lower side of the die pad 20 can be suppressed more surely.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components included in semiconductor devices from known art; and such practice is included in the scope of the invention to the extent that similar effects are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a heat sink;
a semiconductor element provided on a mounting surface of the heat sink; and
a sealing body wrapping the heat sink and the semiconductor element, a thickness of a portion of the sealing body on a side of a surface on an opposite side to the mounting surface of the heat sink being smaller than a thickness of a portion of the sealing body on the mounting surface side of the heat sink,
a first concave-convex being provided on the surface on an opposite side to the mounting surface of the heat sink,
a second concave-convex larger than the first concave-convex being provided on a surface crossing the surface on an opposite side to the mounting surface of the heat sink.

2. The device according to claim 1, wherein a surface roughness of the surface provided with the second concave-convex of the heat sink is larger than a surface roughness of the surface provided with the first concave-convex.

3. The device according to claim 2, wherein a linear expansion coefficient of the sealing body is larger than a linear expansion coefficient of the heat sink.

4. The device according to claim 3, wherein the sealing body contains a resin and a filler of a ceramic.

5. The device according to claim 4, wherein
the sealing body has a first portion on a side of a surface on an opposite side to the mounting surface of the heat sink and a second portion including at least part of a portion on the mounting surface side of the heat sink and
a material of the second portion is different from a material of the first portion.

6. The device according to claim 5, wherein a thermal conductivity of the first portion is higher than a thermal conductivity of the second portion.

7. The device according to claim 6, wherein a surface on an opposite side to the mounting surface of the sealing body is in thermal contact with a heat sink.

8. The device according to claim 6, wherein a percentage of the filler contained in the first portion is higher than a percentage of the filler contained in the second portion.

9. The device according to claim 6, wherein a linear expansion coefficient of the second portion is smaller than a linear expansion coefficient of the first portion.

10. The device according to claim 1, wherein the thickness of a portion of the sealing body on a side of a surface on an opposite side to the mounting surface of the heat sink is not less than 0.1 mm and not more than 0.5 mm.

11. The device according to claim 2, wherein a surface roughness of the surface provided with the second concave-convex of the heat sink is ten times or more of a surface roughness of the surface provided with the first concave-convex.

12. The device according to claim 1, wherein the second concave-convex is in a trench configuration extending in a direction parallel to the mounting surface.

13. The device according to claim 1, wherein an angle between the crossing surface and an upper wall surface of a concave of the second concave-convex is smaller than 90 degrees.

14. The device according to claim 1, further comprising:
a first lead electrically connected to the semiconductor element; and
a second lead electrically connected to the heat sink.

15. The device according to claim 1, wherein a linear expansion coefficient of the sealing body is larger than a linear expansion coefficient of the heat sink.

16. The device according to claim 1, wherein the sealing body contains a resin and a filler of a ceramic.

17. The device according to claim 1, wherein
the sealing body has a first portion on a side of a surface on an opposite side to the mounting surface of the heat sink and a second portion including at least part of a portion on the mounting surface side of the heat sink and
a material of the second portion is different from a material of the first portion.

18. The device according to claim 17, wherein a thermal conductivity of the first portion is higher than a thermal conductivity of the second portion.

19. The device according to claim 1, usable such that a surface on an opposite side to the mounting surface of the sealing body is in thermal contact with a heat dissipation means.

20. A semiconductor device comprising:
a heat sink;
a semiconductor element provided on a mounting surface of the heat sink; and
a sealing body wrapping the heat sink and the semiconductor element, a thickness of a portion of the sealing body on a side of a surface on an opposite side to the mounting surface of the heat sink being smaller than a thickness of a portion of the sealing body on the mounting surface side of the heat sink,
the sealing body having a first portion on a side of a surface on an opposite side to the mounting surface of the heat sink and a second portion including at least part of a portion on the mounting surface side of the heat sink,
a material of the second portion being different from a material of the first portion,
a thermal conductivity of the first portion being higher than a thermal conductivity of the second portion.
